(19) United States
(12) Patent Application Publication
(10) Pub. No.: US 2009/0039510 A1
(43) Pub. Date: Feb. 12, 2009

(54) SEMICONDUCTOR DEVICE AND MANUFACTURING METHOD THEREOF

(75) Inventor: Hiroyasu JOBETTO, Hachioji-shi (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Casio Computer Co., Ltd., Tokyo (JP)

(21) Appl. No.: 12/187,766

(22) Filed: Aug. 7, 2008

(30) Foreign Application Priority Data
Aug. 8, 2007 (JP) 2007-206066

(51) Int. Cl. H01L 23/488; H01L 21/56

(52) U.S. Cl. 257/738; 438/114; 257/E23.023; 257/E21.502

(57) ABSTRACT

A semiconductor device includes a semiconductor construct constructed by a semiconductor substrate and a plurality of external connection electrodes provided under the semiconductor substrate. A lower insulating film is provided under and outside the semiconductor construct. A sealing film is provided on the lower insulating film to cover a periphery of the semiconductor construct. A plurality of lower wiring lines are provided under the lower insulating film and connected to the external connection electrodes of the semiconductor construct, respectively.

### CROSS-REFERENCE TO RELATED APPLICATIONS

This application is based upon and claims the benefit of priority from prior Japanese Patent Application No. 2007-206066, filed Aug. 8, 2007, the entire contents of which are incorporated herein by reference.

### BACKGROUND OF THE INVENTION

1. Field of the Invention

This invention relates to a semiconductor device and a manufacturing method thereof.

2. Description of the Related Art

A conventional semiconductor device described in Jpn. Pat. Appln. KOKAI Publication No. 2000-223518 has a plurality of external connection columnar electrodes provided under a silicon substrate. Such a conventional semiconductor device has a configuration in which the external connection electrodes are provided in a planar areal region of a semiconductor construct (Fan-in), and therefore has a large number of external connection electrodes arranged, so that it can not he applied when the arrangement pitch is smaller than a predetermined dimension, for example, about 0.5 μm.

Jpn. Pat. Appln. KOKAI Publication No. 2005-216935 has disclosed a semiconductor device which is applicable when the number of external connection electrodes arranged is large and which is reduced in size, wherein a semiconductor construct called a chip size package (CSP) is provided on a base plate having a planar size larger than that of the semiconductor construct, and substantially the whole region of this base plate serves as a region for the arrangement of the external connection electrodes of the semiconductor construct (Fan-out).

The conventional semiconductor device described above uses the base plate, and therefore has a problem of an increased thickness of the whole device.

### BRIEF SUMMARY OF THE INVENTION

It is therefore an object of this invention to provide a semiconductor device and a manufacturing method thereof capable of a thickness reduction when a region for the arrangement of external connection electrodes is larger than a planer size of a semiconductor construct.

A semiconductor device according to one aspect of this invention comprises: a semiconductor construct having a semiconductor substrate and a plurality of external connection electrodes provided under the semiconductor substrate; and a lower insulating film provided under and around the semiconductor construct. A sealing film covering the periphery of the semiconductor construct is provided on the lower insulating film, and lower wiring lines connected to the external connection electrodes of the semiconductor construct are provided under the lower insulating film. The lower insulating film is the remainder of a base member after removed.

A semiconductor device manufacturing method according to another aspect of this invention comprises: providing a base substrate having a lower insulating film; fixing a plurality of semiconductor constructs on the lower insulating film, each of the semiconductor constructs including a semiconductor substrate and a plurality of external connection electrodes provided under the semiconductor substrate; forming, on the lower insulating film, a sealing film covering peripheries of the semiconductor constructs. After the sealing film has been formed, the base plate is removed. Then, a lower wiring line is formed under the lower insulating film so that this lower wiring line is connected to the external connection electrodes of the semiconductor construct, and the lower insulating film and the sealing film between the semiconductor constructs are cut to obtain a plurality of semiconductor devices.

According to this invention, the lower wiring line is provided under the lower insulating film provided under and around the semiconductor construct so that this lower wiring line is connected to the external connection electrodes of the semiconductor construct, and no base plate is provided, thereby enabling a thickness reduction in a semiconductor device in which a region for the arrangement of external connection electrodes is larger than a planer size of a semiconductor construct.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a sectional view of a semiconductor device as a first embodiment of this invention;

FIG. 2 is a sectional view of an initial step in one example of a method of manufacturing the semiconductor device shown in FIG. 1;

FIG. 3 is a sectional view of a step following FIG. 2;

FIG. 4 is a sectional view of a step following FIG. 3;

FIG. 5 is a sectional view of a step following FIG. 4;

FIG. 6 is a sectional view of a step following FIG. 5;

FIG. 7 is a sectional view of a step following FIG. 6;

FIG. 8 is a sectional view of a step following FIG. 7;

FIG. 9 is a sectional view of a step following FIG. 8;

FIG. 10 is a sectional view shown to explain a predetermined step in another example of a method of manufacturing the semiconductor device shown in FIG. 1;

FIG. 11 is a sectional view of a semiconductor device as a second embodiment of this invention;

FIG. 12 is a sectional view of an initial step in one example of a method of manufacturing the semiconductor device shown in FIG. 11;

FIG. 13 is a sectional view of a step following FIG. 12;

FIG. 14 is a sectional view of a step following FIG. 13;

FIG. 15 is a sectional view of a step following FIG. 14;

FIG. 16 is a sectional view of a step following FIG. 15;

FIG. 17 is a sectional view of a step following FIG. 16;

FIG. 18 is a sectional view of a semiconductor device as a third embodiment of this invention;

FIG. 19 is a sectional view of a semiconductor device as a fourth embodiment of this invention;

FIG. 20 is a sectional view of a semiconductor device as a fifth embodiment of this invention;

FIG. 21 is a sectional view of a semiconductor device as a sixth embodiment of this invention;

FIG. 22 is a sectional view of a semiconductor device as a seventh embodiment of this invention;

FIG. 23 is a sectional view of a semiconductor device as an eighth embodiment of this invention; and

FIG. 24 is a sectional view of a semiconductor device as a ninth embodiment of this invention.

### DETAILED DESCRIPTION OF THE INVENTION

### First Embodiment

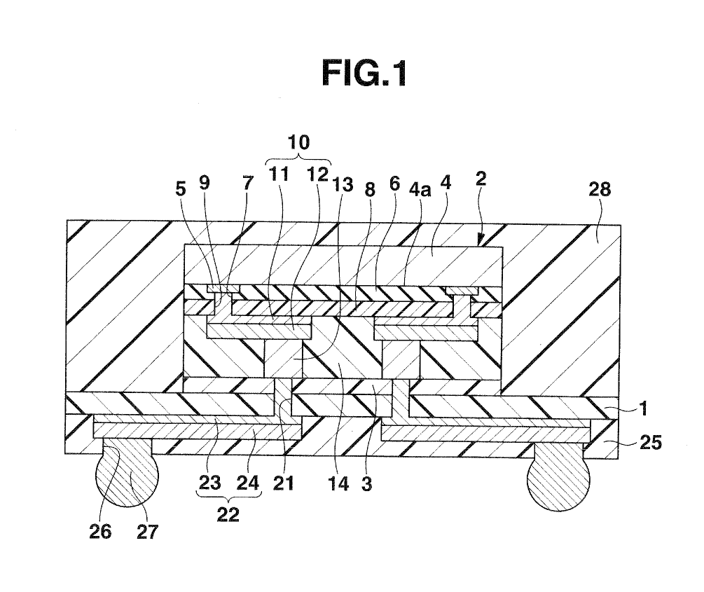

FIG. 1 shows a sectional view of a semiconductor device as a first embodiment of this invention. This semiconductor device comprises a planar square lower insulating film 1 made of, for example, an epoxy resin, a polyimide resin, or an epoxy resin having a glass cloth base material. A planar square semiconductor construct 2 is installed on or fixedly attached on the substantial center or central region of the upper surface of the lower insulating film 1 via an adhesive layer 3 made of, for example, an epoxy resin. In this case, the planar size of the lower insulating film 1 is larger than the planar size of the semiconductor construct 2.

The semiconductor construct 2 includes a planar square silicon substrate (semiconductor substrate) 4. An integrated circuit (not shown) having a predetermined function is provided on a lower surface 4a of the silicon substrate 4. On the peripheral parts of this lower surface 4a, a plurality of connection pads 5 made of, for example, an aluminum-based metal are provided so that these connection pads are electrically connected to the integrated circuit. An insulating film 6 made of, for example, silicon oxide is provided on the lower surface of the silicon substrate 4, and the connection pads 5 except for the centers of the connection pads 5 which are exposed via openings 7 provided in the insulating film 6.

A protective film 8 made of, for example, a polyimide resin is provided on the lower surface of the insulating film 6. Openings 9 are provided in parts of the protective film 8 corresponding to the openings 7 of the insulating film 6. Wiring lines 10 are provided on the lower surface of the protective film 8. Each of the wiring lines 10 has a double-layer structure composed of a foundation metal layer 11 made of copper and provided on the lower surface of the protective film 8, and an upper metal layer 12 made of copper and provided on the lower surface of the foundation metal layer 11. One end of the wiring line 10 is electrically connected to the connection pad 5 via the opening 7 in the insulating film 6 and the opening 9 of the protective film 8.

A columnar electrode (external connection electrode) 13 made of copper is provided at the other end or a connection pad portion of the wiring line 10. A sealing resin film or layer 14 made of, for example, an epoxy resin is provided on the lower surface of the protective film 8 and the wiring lines 10 in such a manner as to enclose the columnar electrodes 13. The lower surface of the sealing resin film 14 is flush with the lower surfaces of the columnar electrodes 13. The lower surfaces of the columnar electrodes 13 and the sealing resin film 14 of the semiconductor construct 2 are adhesively bonded to the central region of the upper surface of the lower insulating film 1 via the adhesive layer 3 made of, for example, an epoxy resin, such that the semiconductor construct 2 is installed on the center of the upper surface of the lower insulating film 1.

A plurality of openings 21 are provided in parts of the lower insulating film 1 and the adhesive layer 3 corresponding to the centers of the lower surfaces of the columnar electrodes 13 of the semiconductor construct 2. Lower wiring lines 22 are provided on the lower surface of the lower insulating film 1. Each of the lower wiring lines 22 has a double-layer structure composed of a foundation metal layer 23 made of copper and provided on the lower surface of the lower insulating film 1, and an upper metal layer 24 made of copper and provided on the lower surface of the foundation metal layer 23. One end of the lower wiring line 22 is electrically connected to the columnar electrode 13 of the semiconductor construct 2 via the openings 21 in the lower insulating film 1 and the columnar electrode 13.

A lower overcoat film 25 made of, for example, a solder resist is provided on the lower surfaces of the lower wiring lines 22 and the lower surface of the lower insulating film 1. An opening 26 is formed at a portion corresponding to the other end or a connection pad portion of the lower wiring line 22, in a part of the lower overcoat film 25. A solder ball 27 is provided in and under the opening 26 of the lower overcoat film 25 so that this solder ball is electrically and mechanically connected to the connection pad portion of the lower wiring line 22. A sealing film 28 or layer made of, for example, an epoxy resin is provided on the upper surface of the semiconductor construct 2 and on the upper surface of the lower insulating film 1 to surround the semiconductor construct 2.

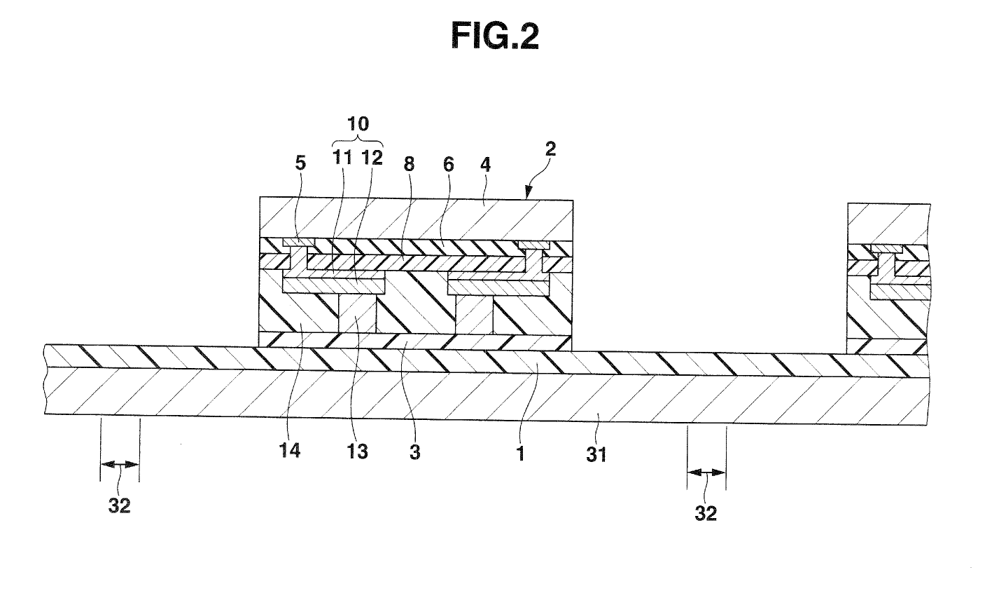

Next, one example of a method of manufacturing this semiconductor device is described. First, as shown in FIG. 2, a unit is prepared wherein the lower insulating film 1 made of, for example, an epoxy resin, a polyimide resin, or an epoxy resin having a glass cloth base material is formed on the upper surface of a base plate (base substrate) 31 made of copper foil. In this case, this prepared unit is sized so that a plurality of completed semiconductor devices shown in FIG. 1 can be formed. Further, in FIG. 2, regions indicated by signs 32 are regions corresponding to cut lines for division into pieces.

Furthermore, the semiconductor construct 2 is prepared. In order to obtain this semiconductor construct 2, the integrated circuit (not shown), the connection pads 5 made of, for example, an aluminum-based metal, the insulating film 6 made of, for example, silicon oxide, the protective film 8 made of, for example, an epoxy resin, the wiring lines 10 (the foundation metal layers 11 made of copper and the upper metal layers 12 made of copper), the columnar electrodes 13 made of copper, and the sealing resin film 14 made of, for example, an epoxy resin are formed under the silicon substrate 4 in a wafer state, and these are then divided into pieces by dicing.

Then, the lower surfaces of the columnar electrodes 13 and the sealing resin film 14 of the semiconductor construct 2 are adhesively bonded to a semiconductor construct installation region on the upper surface of the lower insulating film 1 via the adhesive layer 3 made of, for example, an epoxy resin, such that the semiconductor construct 2 is installed thereon. In this case, the semiconductor construct installation region on the upper surface of the lower insulating film 1 is previously supplied with an adhesive called a non-conductive paste (NCP) using, for example, a printing method or a dispenser or supplied with an adhesive sheet called a non-conductive film (NCF), and the semiconductor construct 2 is fixedly connected to the lower insulating film 1 by hot press bonding. Here, both the NCP and the NCF are resins for flip chip mounting, and are particularly defined as resins which are previously supplied to the lower insulating film 1 and cured together with the connection of the columnar electrode.

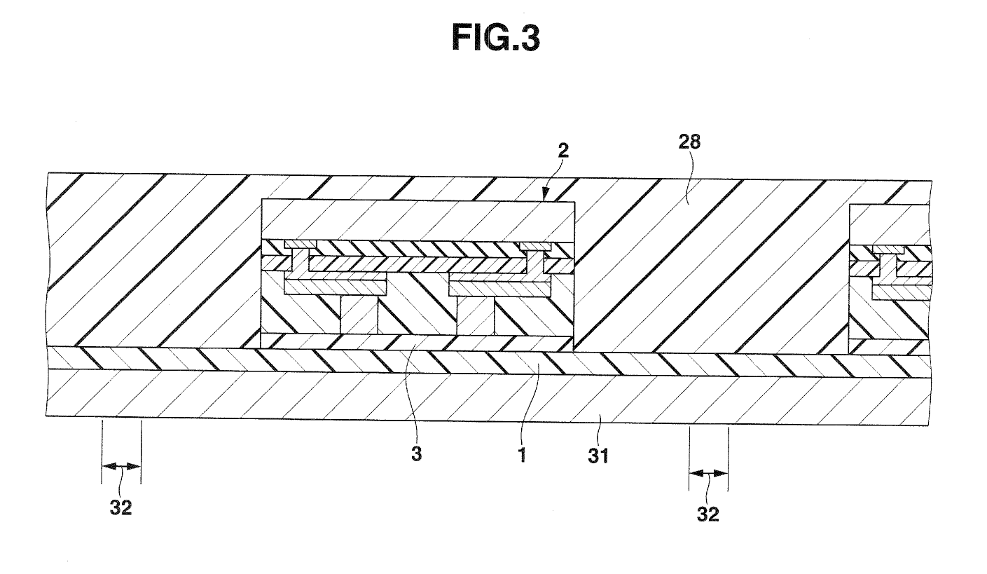

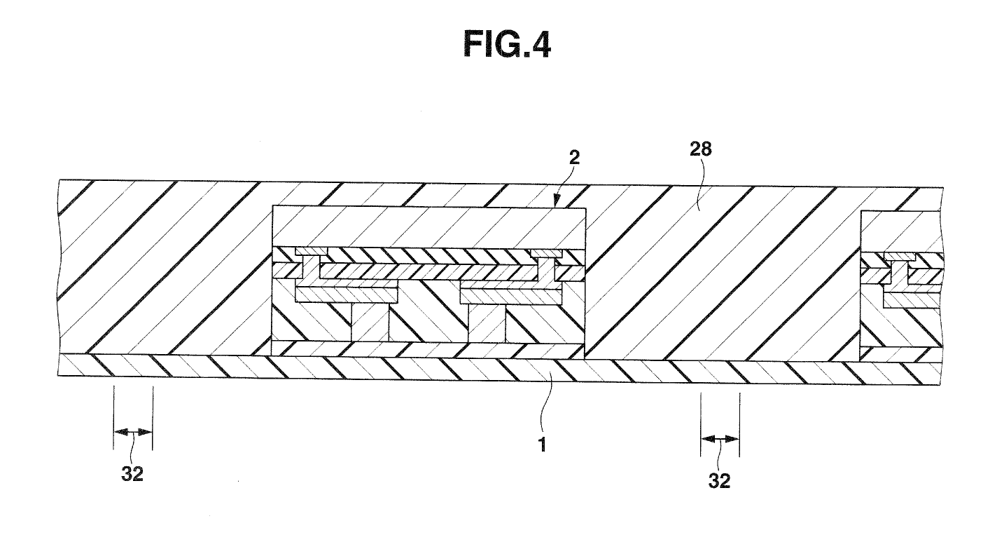

Then, as shown in FIG. 3, the sealing film 28 made of, for example, an epoxy resin is formed on the upper surface of the lower insulating film 1 including the semiconductor construct 2 by a molding method such as a transfer molding method. In addition, the sealing film 28 may be formed by, for example, a screen printing method or a spin coat method. Then, the base plate 31 is removed by etching, such that the lower surface of the lower insulating film 1 is exposed, as shown in FIG. 4. In this state, sufficient strength can be assured owing to the presence of the sealing film 28 and the lower insulating film 1 in spite of the removal of the base plate 31.

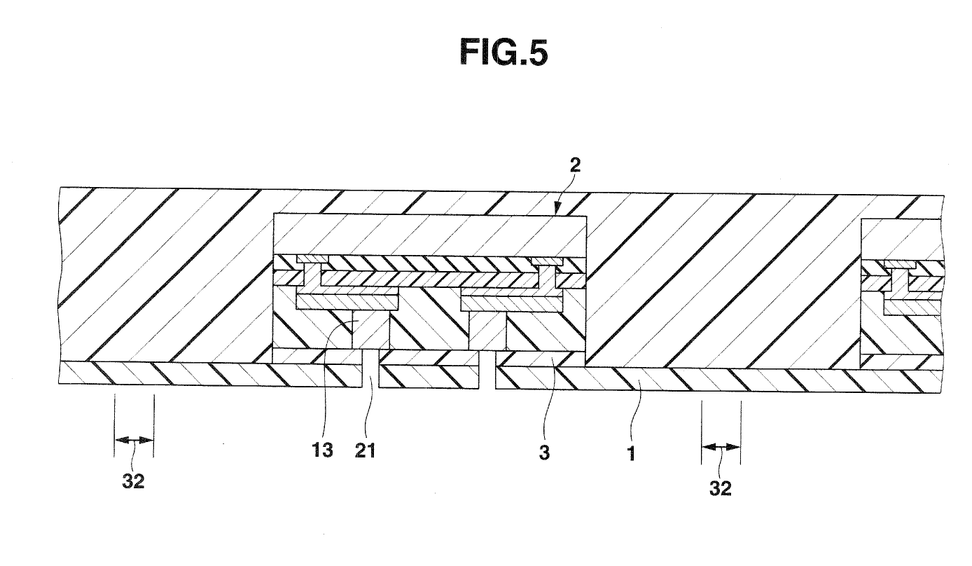

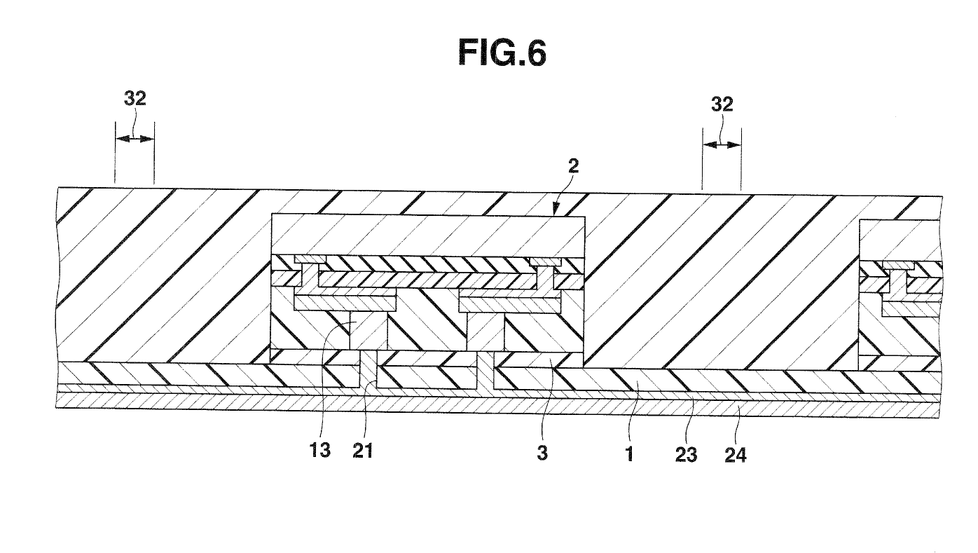

Then, as shown in FIG. 5, the openings 21 are formed by laser processing based on laser beam application in parts of the lower insulating film 1 and the adhesive layer 3 corresponding to the centers of the lower surfaces of the columnar electrodes 13 of the semiconductor construct 2. Then, as shown in FIG. 6, the foundation metal layer 23 is formed by electroless plating with copper over the entire lower surface of the lower insulating film 1 including the lower surfaces of the columnar electrodes 13 of the semiconductor construct 2 which are exposed via the openings 21 in the lower insulating film 1 and the adhesive layer 3.

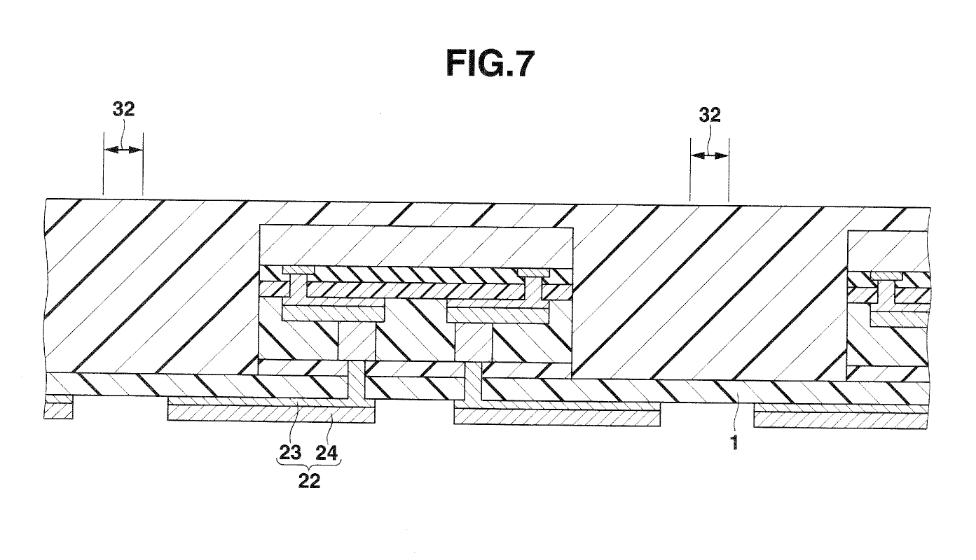

Then, electrolytic plating with copper is carried out using the foundation metal layer 23 as a plating current path, thereby forming the upper metal layer 24 over the entire lower surface of the foundation metal layer 23. Then, the upper metal layer 24 and the foundation metal layer 23 are patterned by a photolithographic method, such that the lower wiring line 22 having the double-layer structure composed of the foundation metal layer 23 and the upper metal layer 24 is formed on the lower surface of the lower insulating film 1, as shown in FIG. 7.

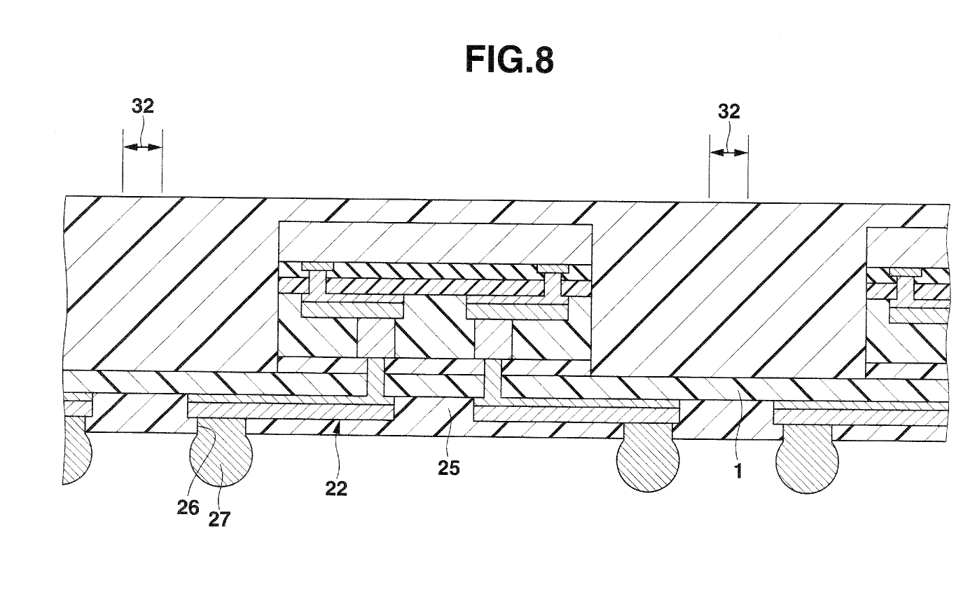

Then, as shown in FIG. 8, the lower overcoat film 25 made of, for example, a solder resist is formed on the lower surface of the lower insulating film 1 including the lower wiring lines 22 by, for example, the screen printing method or the spin coat method. Then, the opening 26 is formed in a part of the lower overcoat film 25 corresponding to the connection pad portion of the lower wiring line 22 by the laser processing based on the laser beam application.

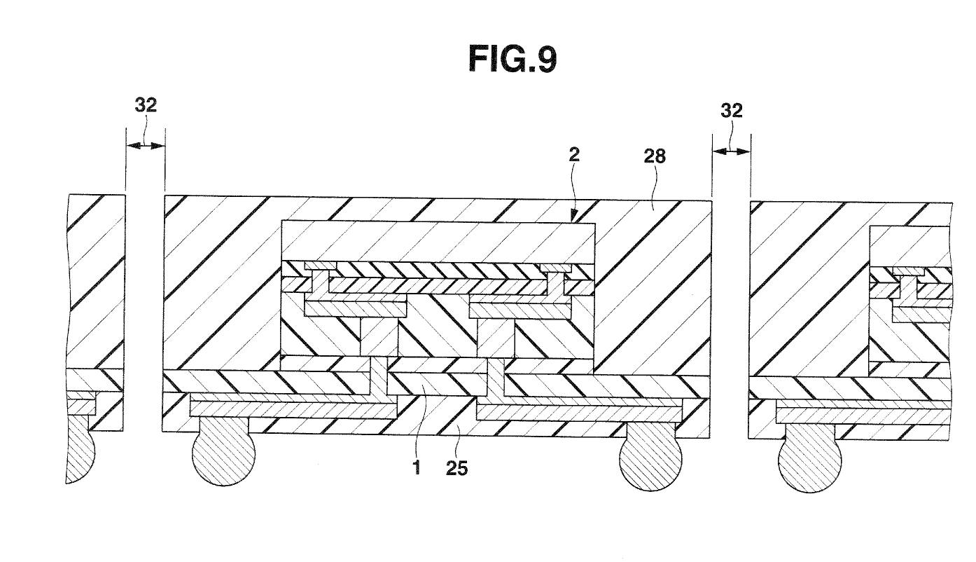

Then, the solder ball 27 is formed in and under the opening 26 of the lower overcoat film 25 so that this solder ball is connected to the connection pad portion of the lower wiring line 22. Then, as shown in FIG. 9, the sealing film 28, the lower insulating film 1 and the lower overcoat film 25 are cut along the cut line 32 between the adjacent semiconductor constructs 2, such that a plurality of semiconductor devices shown in FIG. 1 are obtained.

In the semiconductor device thus obtained, since the lower wiring line 22 is provided under the semiconductor construct 2 and under the lower insulating film 1 provided around the semiconductor construct 2 so that this lower wiring line is connected to the columnar electrode 13 of the semiconductor construct 2, the region for the arrangement of the solder ball (external connection electrode) 27 is larger than the planar size of the semiconductor construct 2 (Fan-out), and no base plate 31 is provided, thereby enabling a thickness reduction. In addition, the base plate 31 may be formed by other metals such as aluminum.

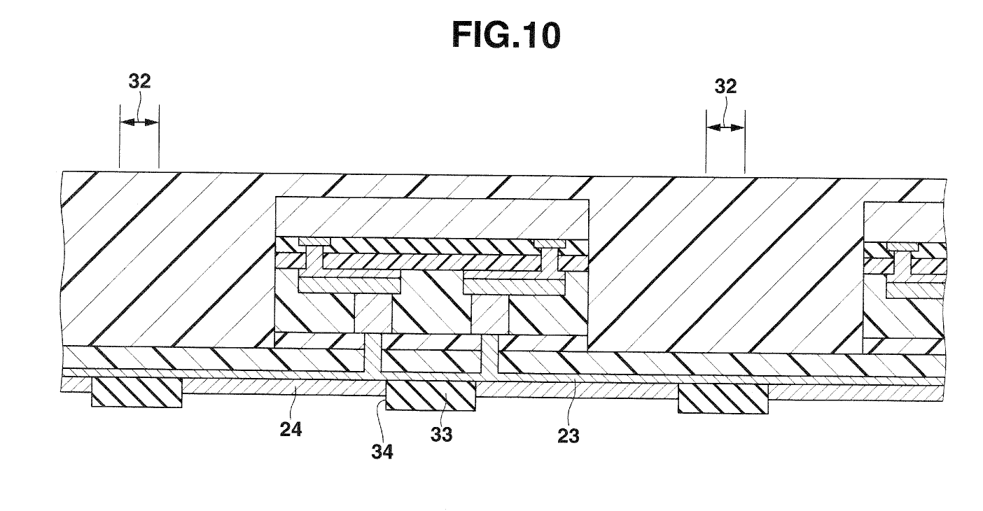

On the other hand, the step shown in FIG. 6 may be as shown in FIG. 10 after the foundation metal layer 23 has been formed. That is, a plating resist film 33 is patterned/formed on the lower surface of the foundation metal layer 23. In this case, an opening 34 is formed in a part of the plating resist film 33 corresponding to the region where the upper metal layer 24 is formed.

Then, electrolytic plating with copper is carried out using the foundation metal layer 23 as a plating current path, thereby forming the upper metal layer 24 on the lower surface of the foundation metal layer 23 within the opening 34 of the plating resist film 33. Then, the plating resist film 33 is released, and unnecessary parts of the foundation metal layer 23 are etched and removed using the upper metal layer 24 as a mask, such that the foundation metal layer 23 remains on the upper metal layer 24 alone, as shown in FIG. 7.

### Second Embodiment

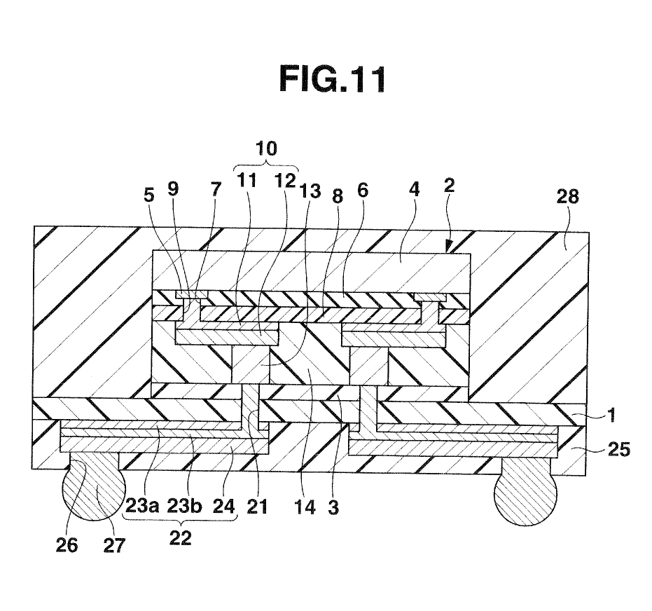

FIG. 11 shows a sectional view of a semiconductor device as a second embodiment of this invention. This semiconductor device is different from the semiconductor device shown in FIG. 1 in that a lower wiring line 22 has a triple-layer structure composed of a first foundation metal layer 23a made of copper, a second foundation metal layer 23b made of copper, and an upper metal layer 24 made of copper. Openings 21 are provided in parts of a lower insulating film 1, an adhesive layer or insulating layer 3 and the first foundation metal layer 23a corresponding to the centers of the lower surfaces of columnar electrodes 13 of a semiconductor construct 2. The second foundation metal layer 23b is connected to the columnar electrode 13 via the opening 21.

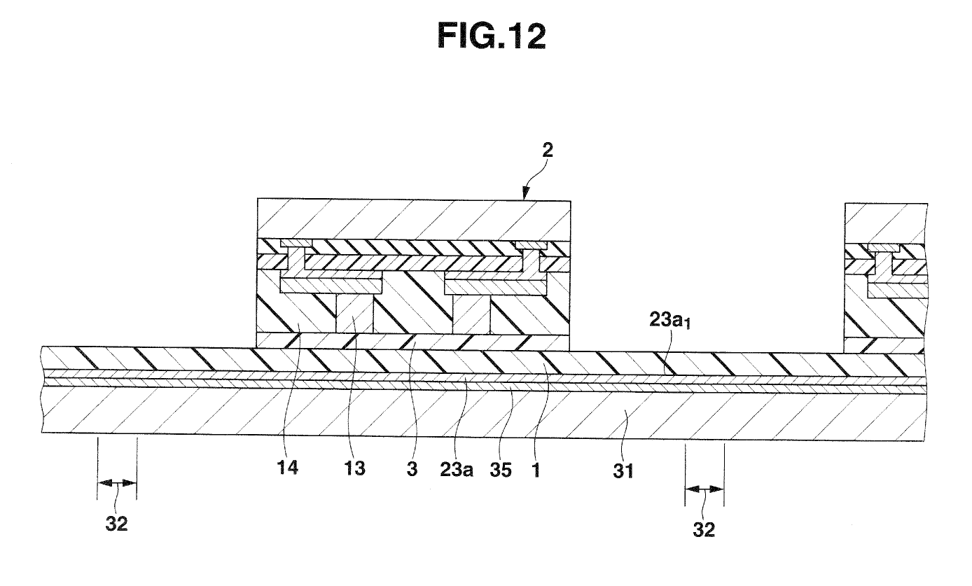

Next, one example of a method of manufacturing this semiconductor device is described. First, as shown in FIG. 12, a base substrate is prepared wherein a protective metal layer 35 made of electroless nickel plating and the first foundation metal layer 23a made of electroless copper plating on the upper surface of the base plate 3 made of a copper foil (metal layer). The lower insulating film 1 made of, for example, an epoxy resin, a polyimide resin, or an epoxy resin having a glass cloth base material is formed on the upper surface of the base substrate.

In this case as well, this prepared unit is sized so that a plurality of completed semiconductor devices shown in FIG. 11 can be formed. Further, in FIG. 12, regions indicated by signs 32 are regions corresponding to cut lines for division into pieces. Here, an upper surface 23a1 of the first foundation metal layer 23a is a surface roughened by surface roughening in order to have a closer contact with the lower insulating film 1 which is made of a material containing a resin and which is formed on this upper surface. This is the feature significantly different from the first embodiment described above. Here, one example of the surface roughening includes a method which immerses the upper surface of the first foundation metal layer 23a in a proper etching solution, but it is not limited to this method.

Then, the lower surfaces of the columnar electrodes 13 and a sealing resin film 14 of the semiconductor construct 2 are adhesively bonded to a semiconductor construct installation region on the upper surface of the lower insulating film 1 via the adhesive layer 3 made of, for example, an epoxy resin, such that the semiconductor construct 2 is installed thereon. In this case as well, the semiconductor construct installation region on the upper surface of the lower insulating film 1 is previously supplied with an adhesive called a non-conductive paste (NCP) or an adhesive sheet called a non-conductive film (NCF), and the semiconductor construct 2 is fixedly connected to the lower insulating film 1 by hot press bonding.

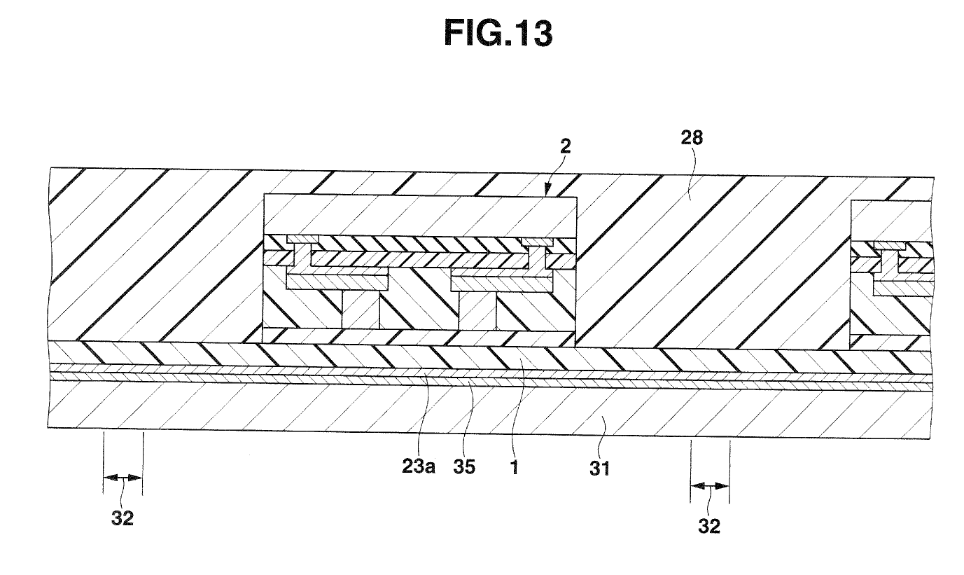

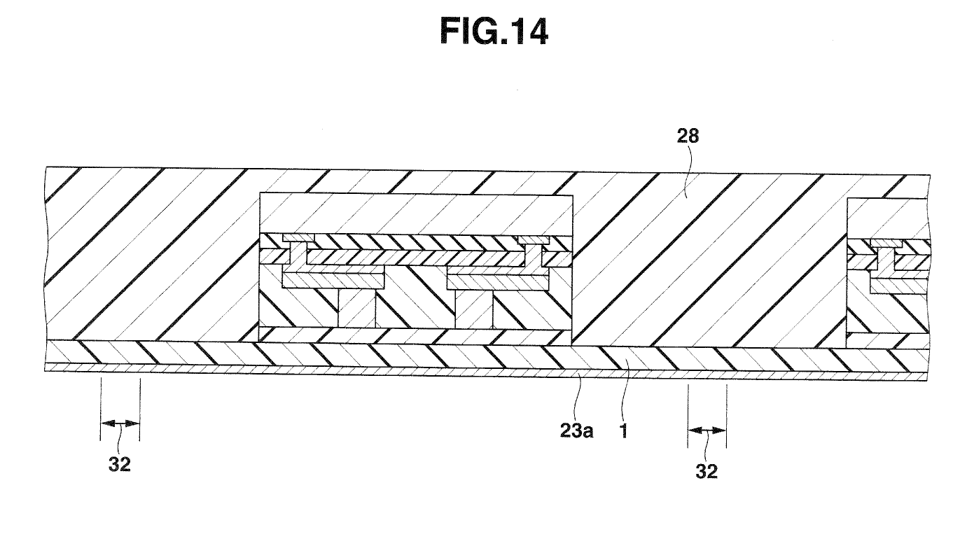

Then, as shown in FIG. 13, a sealing film 28 made of, for example, an epoxy resin is formed on the upper surface of the lower insulating film 1 including the semiconductor construct 2 by, for example, the screen printing method, the spin coat method or the transfer molding method. Then, the base plate 31 and the protective metal layer 35 are sequentially removed by etching, such that the lower surface of the first foundation metal layer 23a is exposed, as shown in FIG. 14.

In this case, when the base plate 31 made of copper is removed by etching, the protective metal layer 35 made of nickel protects the first foundation metal layer 23a which is also made of copper from being etched. Further, in this state, sufficient strength can be assured owing to the presence of the sealing film 28, the lower insulating film 1 and the first foundation metal layer 23a in spite of the removal of the base plate 31 and the protective metal layer 35.

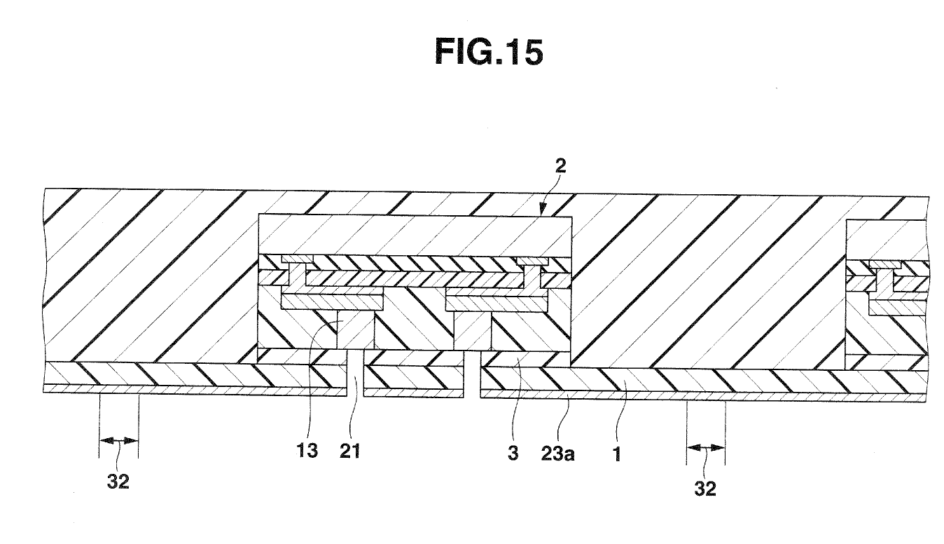

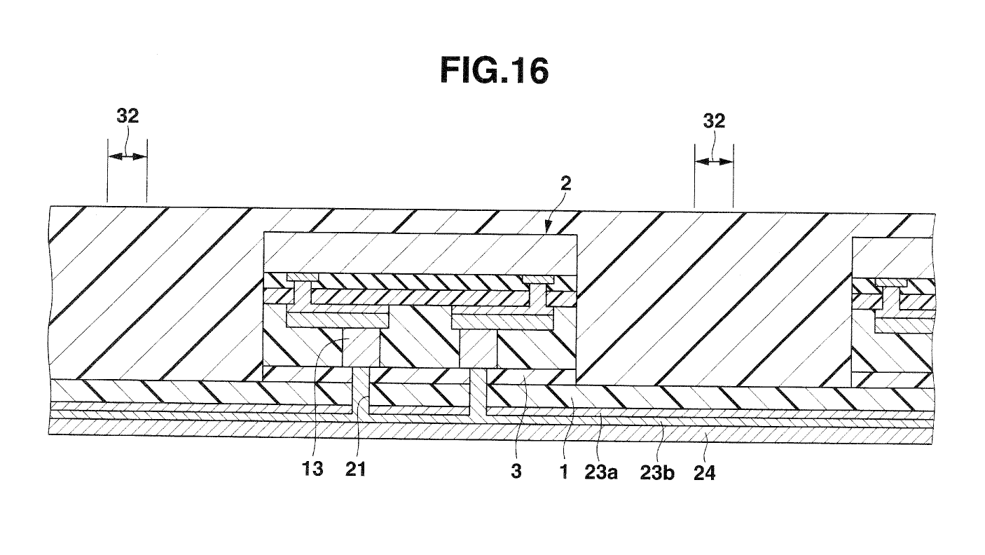

Then, as shown in FIG. 15, the openings 21 are formed by laser processing based on laser beam application in parts of the first foundation metal layer 23a, the lower insulating film 1 and the adhesive layer 3 corresponding to the centers of the lower surfaces of the columnar electrodes 13 of the semiconductor construct 2. Then, as shown in FIG. 16, the second foundation metal layer 23b is formed by electroless plating with copper over the entire lower surface of the first foundation metal layer 23a including the lower surfaces of the columnar electrodes 13 of the semiconductor construct 2 which are exposed via the openings 21 in the lower insulating film 1 and the adhesive layer 3.

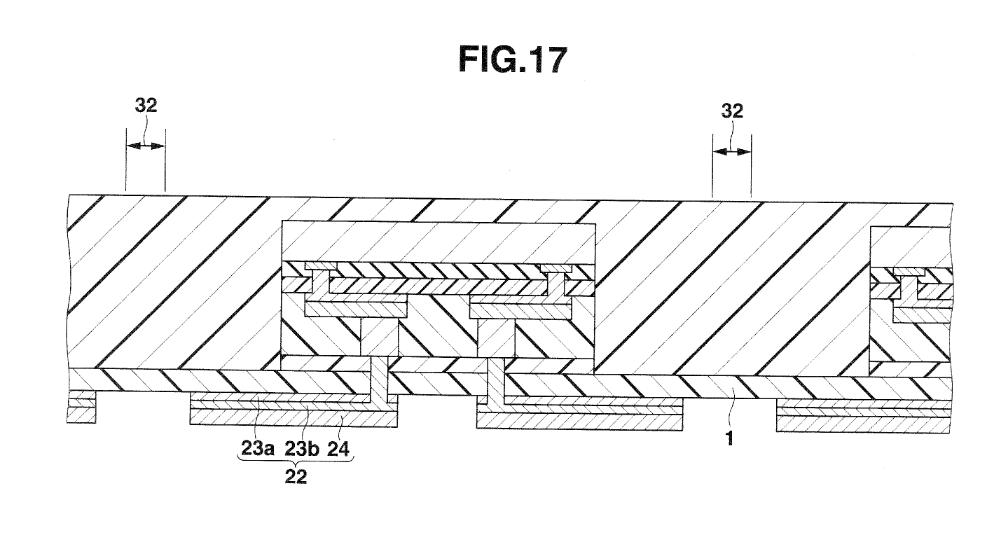

Then, electrolytic plating with copper is carried out using the first and second foundation metal layers 23a, 23b as plating current paths, thereby forming the upper metal layer 24 over the entire lower surface of the second foundation metal layer 23b. Then, the upper metal layer 24 and the first and second foundation metal layers 23a, 23b are patterned by the photolithographic method, such that the lower wiring line 22 having the triple-layer structure composed of the first and second foundation metal layers 23a, 23b and the upper metal layer 24 is formed on the lower surface of the lower insulating film 1, as shown in FIG. 17. Subsequently, a plurality of semiconductor devices shown in FIG. 11 are obtained after steps similar to those in the first embodiment described above.

### Third Embodiment

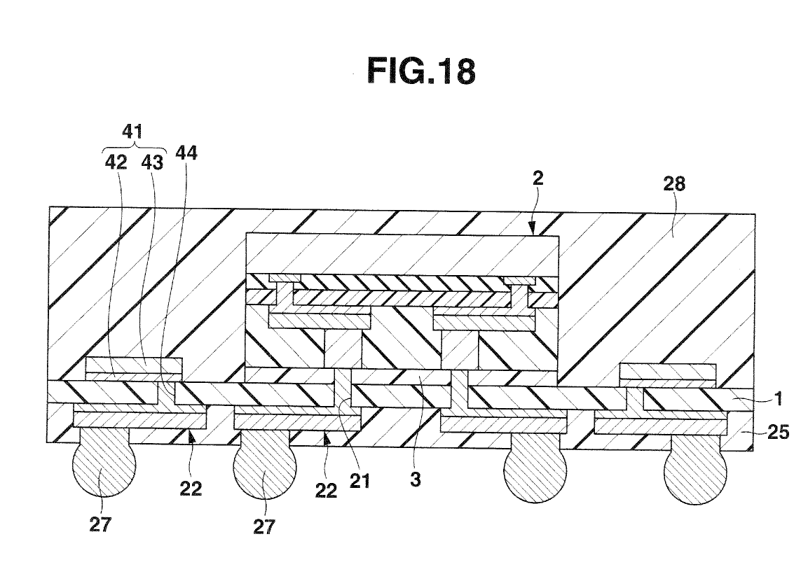

FIG. 18 shows a sectional view of a semiconductor device as a third embodiment of this invention. This semiconductor device is greatly different from the semiconductor device shown in FIG. 1 in that an upper wiring line 41 having a double-layer structure composed of a foundation metal layer 42 made of electroless copper plating and an upper metal layer 43 made of electrolytic copper plating is previously formed on the upper surface of a lower insulating film 1 around a semiconductor construct 2, and each of the upper wiring lines 41 is connected to a different lower wiring line 22. That is, for example, as shown in FIG. 2, the upper wiring line 41 is formed before the semiconductor construct 2 is installed on the upper surface of the lower insulating film 1 formed on the upper surface of a base plate 31.

Then, for example, in a step as shown in FIG. 5, openings 44 are formed in parts of the lower insulating film 1 corresponding to connection pad portions of the upper wiring lines 41 simultaneously with the formation of openings 21 in the lower insulating film 1 and the adhesive layer 3. A part of the lower wiring line 22 is connected to connection pad portion of the upper wiring line 41 via the opening 44.

### Fourth Embodiment

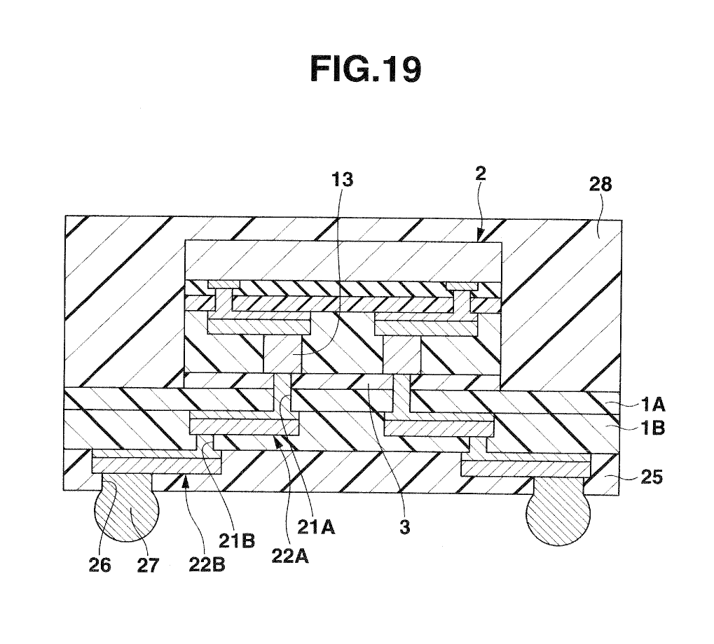

FIG. 19 shows a sectional view of a semiconductor device as a fourth embodiment of this invention. This semiconductor device is greatly different from the semiconductor device shown in FIG. 1 in that a lower wiring line has a double-layer wiring structure. That is, one end of a first lower wiring line 22A provided on the lower surface of a first lower insulating film 1A is connected to a columnar electrode 13 of a semiconductor construct 2 via an opening 21A provided in the first lower insulating film 1A and an adhesive layer 3. A second lower insulating film 1B made of the same material as the first lower insulating film 1A is provided on the lower surface of the first lower wiring line 22A and the lower surface of the first lower insulating film 1A.

One end of a second lower wiring line 22B provided on the lower surface of the second lower insulating film 1B is connected to the other end or a connection pad portion of the first lower wiring line 22A via an opening 21B provided in the second lower insulating film 1B. A lower overcoat film 25 is provided on the lower surface of the second lower wiring line 22B and the lower surface of the second lower insulating film 1B. A solder ball 27 is provided in and under an opening 26 of the lower overcoat film 25 so that this solder ball is connected to a connection pad portion of the second lower wiring line 22B. In addition, the lower wiring line may have a wiring structure of three or more layers.

### Fifth Embodiment

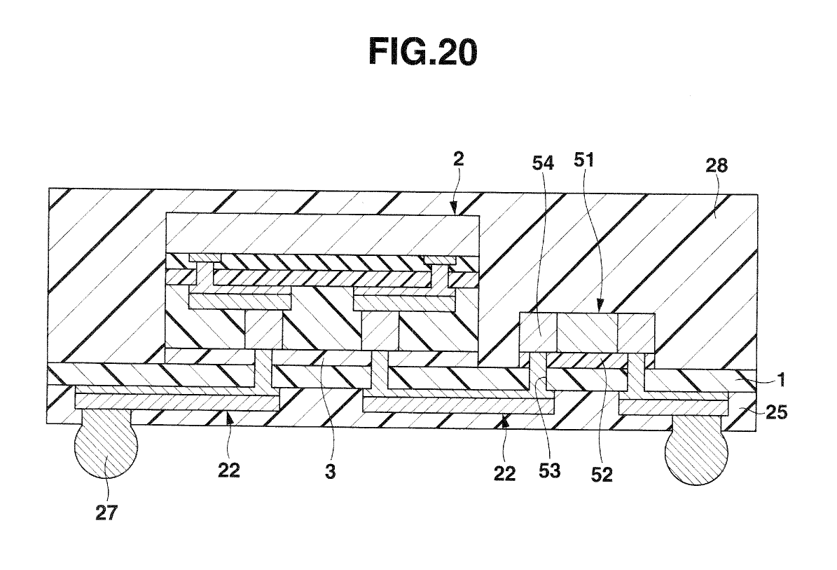

FIG. 20 shows a sectional view of a semiconductor device as a fifth embodiment of this invention. This semiconductor device is greatly different from the semiconductor device shown in FIG. 1 in that a chip component 51 comprising a resistor, a condenser, etc. is adhesively bonded to the upper surface of a lower insulating film 1 around a semiconductor construct 2 via an adhesive layer 52. In this case, one end of each of two or a pair of lower wiring lines (a lower wiring line connected to a columnar electrode, and a new lower wiring line which is not directly connected to the columnar electrode) 22 is connected to both electrodes 54 of the chip component 51 via an opening 53 formed in the lower insulating film 1 and the adhesive layer 52.

### Sixth Embodiment

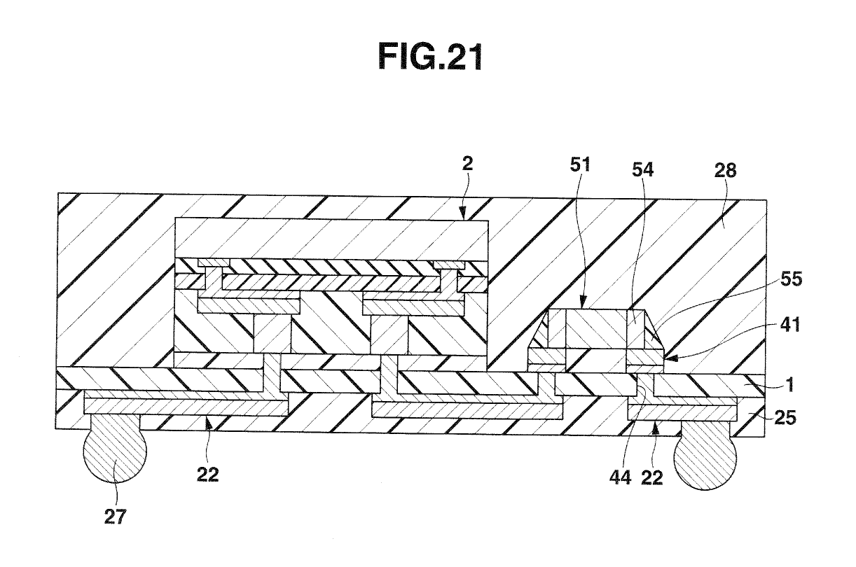

FIG. 21 shows a sectional view of a semiconductor device as a sixth embodiment of this invention. This semiconductor device is greatly different from the semiconductor device shown in FIG. 18 in that an upper wiring line 41 is provided on the upper surface of a lower insulating film 1 around a semiconductor construct 2, and a chip component 51 is installed on the upper surface of this upper wiring line. Both electrodes 54 of the chip component 51 are connected to the upper wiring line 41 via a solder 55. In this configuration, a lower wiring line 22 is divided into a part connected to a columnar electrode 13 and a part (connection pad portion) provided with a solder ball 27, and these parts are electrically connected to each other via the chip component 51.

### Seventh Embodiment

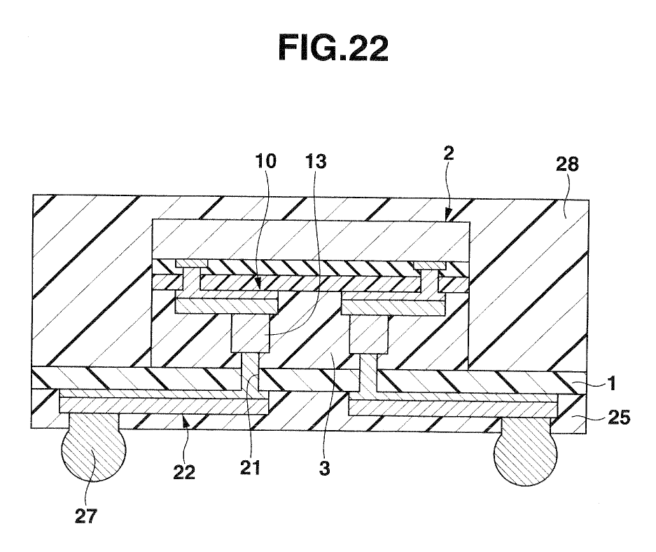

FIG. 22 shows a sectional view of a semiconductor device as a seventh embodiment of this invention. This semiconductor device is different from the semiconductor device shown in FIG. 1 in that a semiconductor construct 2 is not provided with any sealing resin film 14. Therefore, in this case, the lower surfaces of wiring lines 10 of the semiconductor construct 2, the lower surfaces of columnar electrodes 13 and the lower surface of a protective film 8 are adhesively bonded to the center of the upper surface of a lower insulating film 1 via an electrically insulating adhesive layer 3. As a result, the wiring lines 10 and the columnar electrodes 13 are covered with the adhesive layer 3. One end of a lower wiring line 22 is connected to the columnar electrode 13 of the semiconductor construct 2 via openings 21 of the lower insulating film 1 and the adhesive layer 3.

### Eighth Embodiment

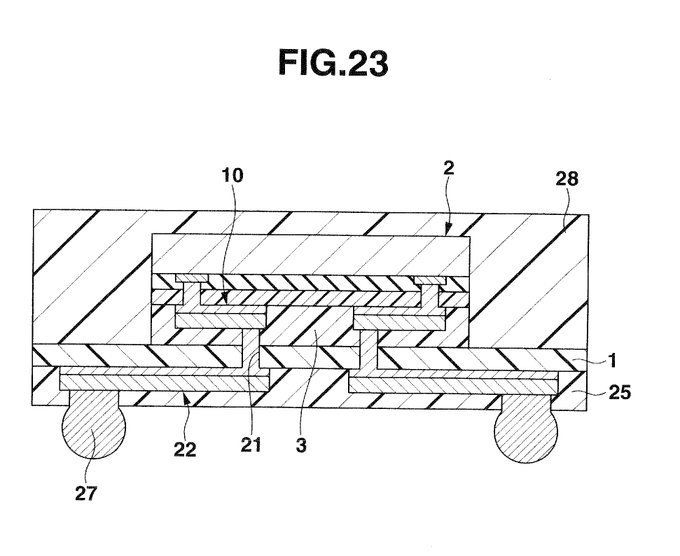

FIG. 23 shows a sectional view of a semiconductor device as an eighth embodiment of this invention. This semiconductor device is different from the semiconductor device shown in FIG. 22 in that a semiconductor construct 2 is not provided with any columnar electrode 13. Therefore, like the device of FIG. 22, the lower surfaces of wiring lines 10 of the semiconductor construct 2 and the lower surface of a protective film 8 are adhesively bonded to the center of the upper surface of a lower insulating film 1 via an adhesive layer 3. One end or inner end of each lower wiring line 22 is electrically connected to a connection pad portion (external connection electrode) of the wiring line 10 of the semiconductor construct 2 via an openings 21 of the lower insulating film 1 and the adhesive layer 3.

### Ninth Embodiment

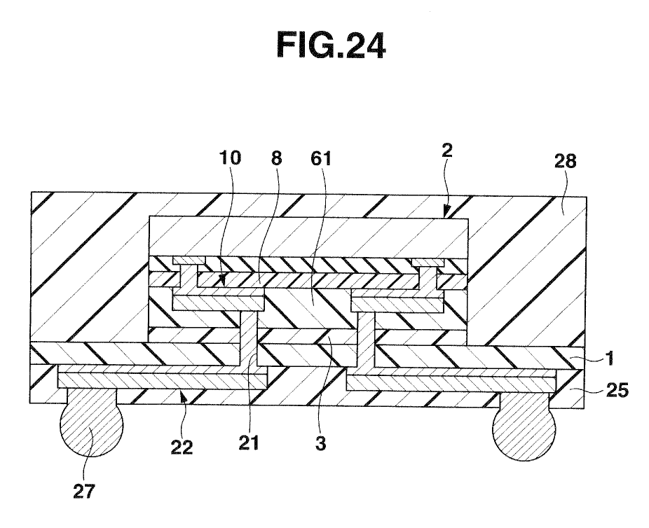

FIG. 24 shows a sectional view of a semiconductor device as a ninth embodiment of this invention. This semiconductor device is different from the semiconductor device shown in FIG. 23 in that a semiconductor construct 2 has an antistatic protective film or layer 61 made of an insulating material such as a polyimide resin or epoxy resin and provided on the lower surfaces of wiring lines 10 of a semiconductor construct 2 and the lower surface of a protective film 8. The lower surface of the protective film 61 is adhesively bonded to the center of the upper surface of a lower insulating film 1 via an adhesive layer 3. Further, one end of each lower wiring line 22 is electrically connected to a connection pad portion of the wiring line 10 of the semiconductor construct 2 via openings 21 of the lower insulating film 1, the adhesive layer 3 and the protective film 61.

The opening 21 is not formed in the protective film 61 before the semiconductor construct 2 is installed on the lower insulating film 1. Thus, the protective film 61 having no opening 21 protects an integrated circuit formed under a silicon substrate 4 against static electricity from the point where the protective film 61 itself has been formed under the silicon substrate 4 in a wafer state to the point where the semiconductor construct 2 is installed on the lower insulating film 1.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor construct including a semiconductor substrate and a plurality of external connection electrodes provided under the semiconductor substrate;
a lower insulating film provided under and outside the semiconductor construct;
a sealing film provided on the lower insulating film to cover a periphery of the semiconductor construct; and
a plurality of lower wiring lines provided under the lower insulating film and connected to the external connection electrodes of the semiconductor construct, respectively.

2. The semiconductor device according to claim 1, wherein the semiconductor construct is bonded on a central region of the lower insulating film via an adhesive layer.

3. The semiconductor device according to claim 1, further comprising a lower overcoat film which is provided under the lower wiring lines and under the lower insulating film and which has openings in parts corresponding to connection pad portions of the lower wiring lines.

4. The semiconductor device according to claim 3, further comprising a plurality of solder balls which are provided in and under the openings of the lower overcoat film so that the solder balls are electrically connected to the connection pad portions of the lower wiring lines, respectively.

5. The semiconductor device according to claim 1, wherein the sealing film covers an upper surface of the semiconductor substrate of the semiconductor construct.

6. The semiconductor device according to claim 1, wherein each of the lower wiring lines has a multilayer structure.

7. The semiconductor device according to claim 1, further comprising at least one upper wiring line which is provided on an upper surface of the lower insulating film around the semiconductor construct so that the upper wiring line is connected to the lower wiring line.

8. The semiconductor device according to claim 7, further comprising a chip component which is provided on the upper wiring line.

9. The semiconductor device according to claim 1, further comprising at least one chip component which is provided on the lower insulating film so that the chip component is connected to the lower wiring line.

10. The semiconductor device according to claim 9, wherein the chip component is adhesively bonded on the lower insulating film via an adhesive layer.

11. The semiconductor device according to claim 1, wherein the semiconductor construct includes a sealing resin film provided around the external connection electrodes under the semiconductor substrate.

12. The semiconductor device according to claim 1, wherein the semiconductor construct includes an adhesive layer provided around the external connection electrodes under the semiconductor substrate.

13. A semiconductor device manufacturing method comprising:
providing a base substrate having a base plate and a lower insulating film;
fixing a plurality of semiconductor constructs on the lower insulating film, each of the semiconductor constructs including a semiconductor substrate and a plurality of external connection electrodes provided under the semiconductor substrate;
forming, on the lower insulating film, a sealing film covering peripheries of the semiconductor constructs;
removing the base plate from the lower insulating film;
forming a plurality of lower wiring lines under the lower insulating film so that each of the lower wiring lines is connected to each of the external connection electrodes of each of the semiconductor constructs; and
cutting the lower insulating film and the sealing film between the semiconductor constructs to obtain a plurality of semiconductor devices.

14. The semiconductor device manufacturing method according to claim 13, wherein the fixing the plurality of semiconductor constructs on the lower insulating film includes previously supplying an adhesive layer onto the lower insulating film and hot-pressing the semiconductor constructs onto the lower insulating film.

15. The semiconductor device manufacturing method according to claim 13, wherein the fixing the semiconductor constructs on the lower insulating film includes previously supplying an adhesive sheet onto the lower insulating film and hot-pressing the semiconductor constructs onto the lower insulating film.

16. The semiconductor device manufacturing method according to claim 13, further comprising forming openings in the lower insulating film and an adhesive layer for fixing the semiconductor construct on the lower insulating film, in parts corresponding to the external connection electrodes of the semiconductor construct, before forming the lower wiring line.

17. The semiconductor device manufacturing method according to claim 13, wherein the base substrate includes a metal layer, a protective metal layer and a first foundation metal layer, and the lower insulating film is formed on the first foundation metal layer, and
the removing the base plate includes removing any layer except the first foundation metal layer.

18. The semiconductor device manufacturing method according to claim 17, wherein before forming the lower insulating film, an upper surface of the first foundation metal layer is roughened, and the lower insulating film is formed by a material containing a resin.

19. The semiconductor device manufacturing method according to claim 18, further comprising forming openings in the first foundation metal layer, the lower insulating film and an adhesive layer for fixing the semiconductor construct on the lower insulating film, in parts corresponding to the external connection electrodes of the semiconductor construct, after removing any layer except the first foundation metal layer of the base substrate.

20. The semiconductor device manufacturing method according to claim 19, wherein the forming the plurality of lower wiring lines includes forming a second foundation metal layer on each of the first foundation metal layers, and forming an upper metal layer on the second foundation metal layer by electrolytic plating; and each of the lower wiring lines has a triple-layer structure including the first and second foundation metal layers and the upper metal layer.

21. The semiconductor device manufacturing method according to claim 20, wherein the metal layer, the first and second foundation metal layers and the upper metal layer are made of copper, and the protective metal layer is made of nickel.

22. The semiconductor device manufacturing method according to claim 13, wherein the providing the base substrate comprises forming an upper wiring line around a semiconductor construct installation region on the lower insulating film, and
the forming the plurality of lower wiring lines under the lower insulating film includes connecting the lower wiring line to the upper wiring line.

23. The semiconductor device manufacturing method according to claim 13, wherein the sealing film is formed by a molding method.
